(19) United States
(12) Patent Application Publication
(10) Pub. No.: US 2011/0049634 A1
(43) Pub. Date: Mar. 3, 2011

(54) METHOD OF MANUFACTURING A SEMICONDUCTOR DEVICE AND SEMICONDUCTOR DEVICE

(75) Inventors: Raghunath Singanamalla, Bangalore (IN); Jacob C. Hooker, Hamburg (DE); Marcus J. H. Van Dal, Heverlee (BE)

(73) Assignees: NXP B.V., Eindhoven (NL); INTERUNIVERSITAIR MICROELEKTRONICA CENTRUM VZW, Leuven (BE)

(21) Appl. No.: 12/935,760

(22) PCT Filed: Mar. 30, 2009
(86) PCT No.: PCT/IB09/51324

§ 371 Date: Nov. 11, 2010

(30) Foreign Application Priority Data
Apr. 2, 2008 (EP) 08103326.8

(51) Int. Cl. H01L 29/78; H01L 21/336

(52) U.S. Cl. 257/366; 438/283; 257/E29.264; 257/E21.409

(57) ABSTRACT

A method of manufacturing a semiconductor device having gate electrodes of a suitable work function material is disclosed. The method comprises providing a substrate (100) including a number of active regions (110, 120) and a dielectric layer (130) covering the active regions (110, 120), and forming a stack of layers (140, 150, 160) over the dielectric layer. The formation of the stack of layers comprises depositing a first metal layer (140), having a first thickness, e.g. less than 10 nm, over the dielectric layer (130), depositing a second metal layer (150) having a second thickness over the first metal layer (140), the second thickness being larger than the first thickness, introducing a dopant (152, 154) into the second metal layer (150), exposing the device to an increased temperature to migrate at least some of the dopant (152, 154) from the second metal layer (150) beyond the interface between the first metal layer (140) and the second metal layer (150); and patterning the stack into a number of gate electrodes (170). This way a gate electrode is formed having an dopant profile in the vicinity of the dielectric layer (130) such that the work function of the gate electrode is optimized, without the gate dielectric suffering from degradation by dopant penetration.

The present invention relates to a method of manufacturing a method of manufacturing a semiconductor device, comprising providing a substrate including a number of active regions and a dielectric layer covering the active regions; and forming a stack of layers over the dielectric layer, comprising depositing a first metal layer having a first thickness over the dielectric layer and depositing a second metal layer having a second thickness over the first metal layer.

The present invention further relates to providing an electronic device manufactured in accordance with said method.

Advances in semiconductor manufacturing are evident from the ongoing downscaling of semiconductor features sizes. To successfully downscale a semiconductor technology, several technical problems associated with the downscaling have to be solved. For instance, the miniaturization of transistor feature sizes includes a reduction of the dimensions of the dielectric gate material, which is well-known to cause an increase in the transistor leakage current. This problem has led to the introduction of so-called high-k dielectric materials as the gate dielectric, which are materials having a dielectric constant that is significantly higher than that of SiO₂. In some cases, high-k dielectric materials have been defined as materials having a dielectric constant of at least 10.

A problem associated with the introduction of high-k materials is that the polysilicon (Poly-Si) gate electrodes are no longer ideally suited to achieve a work function of the gate electrode near the valence band of silicon in case of an n-type transistor or the conduction band of silicon in case of an p-type transistor, which can lead to an undesirable increase of the transistor threshold voltage (Vₜₕ). This has led to the introduction of metal-based gate electrodes, because of the higher conductivity of metals, metal nitrides, metal silicides and other suitable metal-based materials compared to poly-Si. In the context of the present invention, the phrase metal denotes metals as well as suitable metal derivates such as metal nitrides, metal silicides, metal carbides and so on. The metal must be thermally stable, i.e. capable of withstanding the increased temperature steps during the manufacturing of the semiconductor device.

A single semiconductor device may comprise transistors having a different Vₜₕ, such as the p-type and n-type transistors in CMOS devices. The different work function materials required for such transistors can in theory be realized using different metals in the gate electrodes of the different transistors, but such an approach is impractical due to the complexity of the associated manufacturing process. An alternative approach is to deposit the same metal layer over the gate dielectric of different types of transistors, and selectively modifying the work function of the metal layer to tune the work function of the metal to the Vₜₕ of the underlying transistor.

US2001/0015463 A1 describes a method of the type mentioned in the opening paragraph, in which an approximately 100 nm thick layer of titanium is deposited as the first metal layer. Nitrogen ions are locally implanted in this layer to change the work function. An approximately 200 nm thick layer of tungsten is deposited as the layer of the second material. On the layer of tungsten, an etch mask of silicon nitride is formed, after which the gate electrodes are etched in the packet of superposed layers of tungsten and titanium nitride.

If titanium is used as the metal for the gate electrodes, a maximum change, in this case an increase, of the work function is obtained if the layer of titanium, upon the introduction of nitrogen, is completely converted to a layer of titanium nitride. This requires a very large quantity of nitrogen to be implanted; in a layer of titanium having a thickness of 100 nm more than 5.10¹⁷ nitrogen atoms per cm² must be implanted. In practice, this requires an expensive process step which is also very time-consuming. The use of a thinner layer, so that converting this layer of titanium entirely to a layer of titanium nitride would require less nitrogen is impossible in practice because, during the ion implantation, the underlying gate dielectric could be damaged.

This problem is addressed in WO 2004/070833 A1, which describes a method of manufacturing a semiconductor device having MOS transistors. In this method, active silicon regions are provided with a layer of a gate dielectric. A layer of a first metal is deposited in which locally, at the location of a part of the active regions, nitrogen is introduced. On the layer of the first metal, a layer of a second metal is then deposited, after which the gate electrodes are etched in the metal layers. Before nitrogen is introduced into the first metal layer, an auxiliary layer of a third metal which is permeable to nitrogen is deposited on the first metal layer. Consequently, the first metal layer can be nitrided locally without the risk of damaging the underlying gate dielectric. However, this process requires the deposition (and optional removal) of an additional layer, which adds to the overall cost and complexity of the manufacturing process.

The present invention seeks to provide a method of manufacturing a semiconductor device in which the work function of the gate electrode can be manipulated in a less costly manner.

The present invention further seeks to provide a semiconductor device including metal-based gate electrodes having appropriately tuned work functions.

According to a first aspect of the present invention, there is provided a method of manufacturing a semiconductor device, comprising providing a substrate including a number of active regions and a dielectric layer covering the active regions; and forming a stack of layers over the dielectric layer comprising depositing a first metal layer having a first thickness over the dielectric layer; depositing a second metal layer having a second thickness over the first metal layer, the second thickness being larger than the first thickness; introducing a dopant into the second metal layer; exposing the device to an increased temperature to migrate at least some of the dopant from the second metal layer beyond the interface between the first metal layer and the second metal layer; and patterning the stack into a number of gate electrodes.

The present invention uses a thermal processing step to migrate a dopant profile introduced in the second metal layer beyond the interface between the first metal layer and the second metal layer. This obviates the need for an additional layer for introducing the dopant into the gate electrode. The introduction of the dopant into the second metal layer ensures that the risk of damage to the dielectric layer by the introduction of the dopant is reduced. The introduction of the dopant may be realized in any suitable way, such as implantation, exposure to a gaseous environment which may include a plasma enhancement and so on.

The dopant may also be introduced into the second metal layer prior to the deposition of this layer, e.g. be present in the metal prior to deposition as an intrinsic part of the metal. This has the advantage of the further reduction of the number of required manufacturing steps.

The first layer preferably has a higher solubility for the dopant than the second metal layer to promote migration of the dopant from the second metal layer towards the first metal layer. The first metal layer preferably has a thickness of less than 10 nm to facilitate accumulation of the migrated dopant in the first metal layer near its interface with the dielectric layer.

Preferably, the method further comprises depositing a poly-silicon layer over the second metal layer, and wherein the step of increasing the temperature further comprises siliciding the second metal layer. A metal silicide is particularly suitable as a work function material, especially when the dielectric material is a high-k dielectric material. At this point, it is emphasized that the patterning of the stack may be performed either prior to or following the silicidation step.

The device may be subjected to a further increased temperature, which may be higher or lower than the first increased temperature. Such a two-step process may be used to migrate the at least some of the dopant beyond the interface into the first metal layer.

The number of active regions of the semiconductor device may comprise an active region of a first conductivity type and an active region of a second conductivity type. In this case, introducing a dopant into the second metal layer comprises selectively introducing a first dopant into a region of the second metal located over the active region of the first conductivity type; and selectively introducing a second dopant into a region of the second metal located over the active region of the second conductivity type to appropriately tune the work functions of the respective metal gate electrodes.

According to a further aspect of the present invention, a semiconductor device is provided comprising a substrate including a number of active regions; a dielectric layer covering the active regions; and a number of gate electrodes each located over one of said active regions, each gate electrode comprising a stack of layers comprising: a first metal layer having a first thickness, deposited on the dielectric layer; a second metal layer having a second thickness, deposited on the first metal layer, the second thickness being larger than the first thickness; and a dopant profile located near the interface region between the second metal layer and the first metal layer, said dopant profile being shared between the first metal layer and the second metal layer. Such a device is manufactured in accordance with the method of the present invention, and benefits from the aforementioned advantages of the manufacturing method, such as reduced cost and improved integrity of the gate dielectric.

The invention is described in more detail and by way of non-limiting examples with reference to the accompanying drawings, wherein:

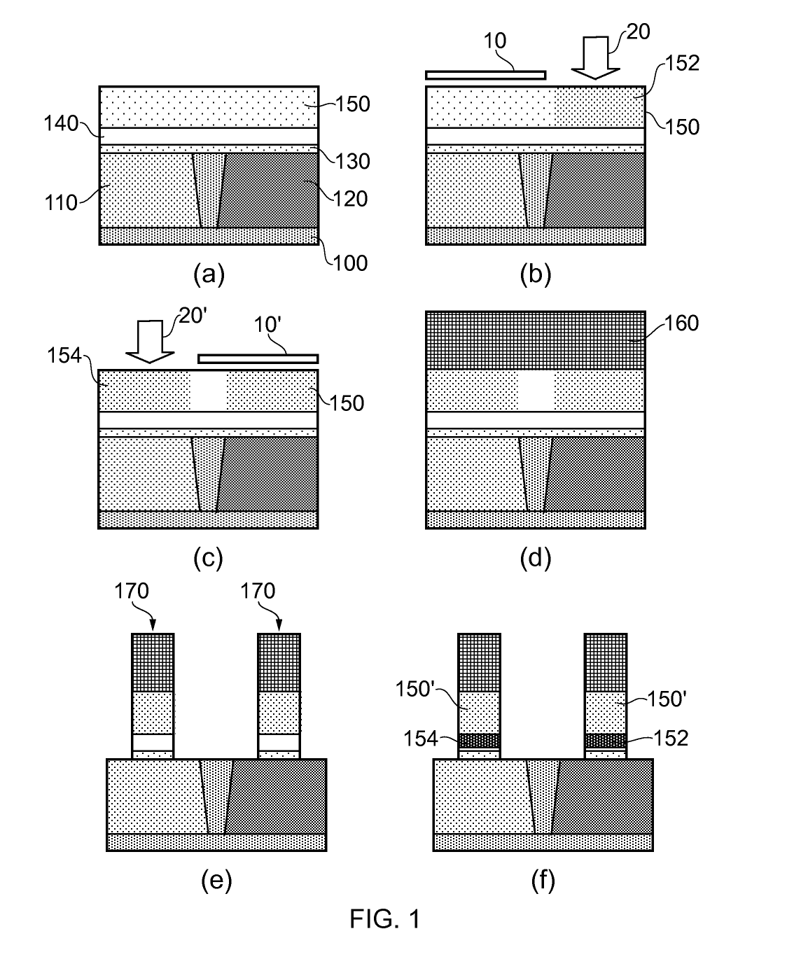

FIG. 1a-f schematically depict intermediate stages in an embodiment of the method according to the present invention; and

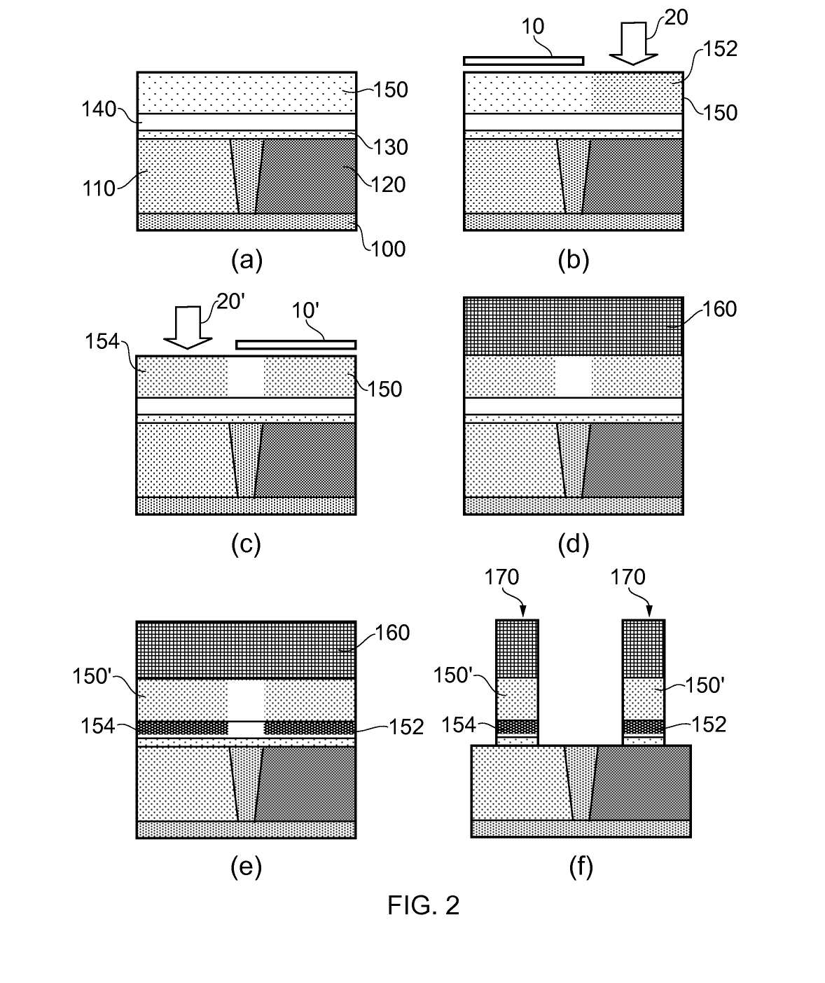

FIG. 2a-f schematically depict intermediate stages in another embodiment of the method according to the present invention.

It should be understood that the Figures are merely schematic and are not drawn to scale. It should also be understood that the same reference numerals are used throughout the Figures to indicate the same or similar parts.

The method and semiconductor device of the present invention will now be explained for a CMOS manufacturing process by way of non-limiting example only. It should be understood that the invention is not limited to CMOS devices; the teachings of the present invention may also be applied to other types of semiconductor devise such as bipolar devices, BiCMOS devices, memory devices and so on.

FIG. 1a shows a first intermediate stage of the semiconductor device manufacturing method of the present invention. The intermediate structure shown in FIG. 1 may be formed using conventional manufacturing steps. A substrate 100 has an n-well 110 and a p-well 120. The n-well 110 and a p-well 120 may be formed in the substrate 100 using any suitable technique. The substrate 100, or at least the active regions formed by the n-well 110 and the p-well 120, is covered by a dielectric layer 130. The dielectric layer may be a standard SiO₂/SiON material or some other high-k material. In the context of the present invention, a high-k material is a material having a dielectric constant of at least 10.

A thin metal layer 140 is deposited over the dielectric layer 130. Preferably, the thickness should be less than 10 nm to allow diffusion and/or penetration of a work function modifying species (dopant) into this layer, as will be explained in more detail later. The metal may be a transition or lanthanide metal or any of its nitride or carbides.

A further metal layer 150, which typically is thicker than the first metal layer 140, is deposited over the thin metal layer 140. To achieve the most efficient diffusion of the function modifying species into the thin metal layer 140, the further metal layer preferably is any transition metal which has a lower solubility for a dopant compared to the solubility of the dopant in the metal of thin metal layer 140. The metal for the thin metal layer 140 may further be chosen to act as a barrier between a metal silicide and the dielectric layer 130. In this case, the metal for the further metal layer 150 must be able to form thermally stable silicide. Non-limiting examples of suitable metals include Ta, TaC, TaN and TiN and mixtures thereof for the thin metal layer 140 and Mo, W and Ru for the further metal layer 150.

Next, a dopant is implanted in the regions of the further metal layer 150 over the n-well 110 (FIG. 1b) and the p-well 120 (FIG. 1c). To this end, masks 10 and 10′ and implants 20 and 20′ may be used to create dopant profiles 152 and 154 in the further metal layer 150. However, the dopant may be introduced in any suitable way. In addition, the dopant may be added to the further metal prior to its deposition, although this requires the deposition of the metal layer 150 in a two-step process to ensure that different dopants are present over the n-well 110 and the p-well 120. A dopant 154 such as As and Te, or even Se, Sb, P, Tb or Yb, can be used in the metal layer 150 over the PWELL region where the nMOSFETs will be formed whereas a dopant 152 such as Al, Er, In and F can be used in the NWELL region where pMOSFETs will be formed. As will be appreciated from e.g. FIG. 1c, the dopant profiles 152 and 154 are located at or near the surface of the further metal layer 150 after e.g. implantation.

In a next step, a layer 160 of poly-Si may be deposited over the further metal layer 150, and this step is typically followed by a gate patterning step (FIG. 1e) in which gate electrodes 170 are formed, and may be further followed by halo and spacer formation (not shown).

In the embodiment of the present invention shown in FIG. 1, the device is subsequently subjected to an increased temperature, i.e. to an appropriate thermal budget, to cause the silicidation of the further metal layer 150. This is shown in FIG. 1f, where the further metal layer 150 is converted into a metal silicide layer 150′. A side-effect of the exposure of the device to the thermal budget is the migration, or diffusion, of the dopant profiles 152 and 154 from the interface between the further metal layer 150 and the poly-Si layer 160 to the interface region between the further metal layer 150 and the thin metal layer 140. This is aided by the higher solubility of the dopant species in the metal of the thin metal layer 140 compared to its solubility in the metal of the further metal layer 150.

Preferably, the dopant profiles 152 and 154 are migrated beyond the interface between the further metal layer 150 and the thin metal layer 140 such that the dopant profiles are located in close vicinity to the interface between the thin metal layer 140 and the dielectric layer 130, where the dopant has the most pronounced effect on the Vₜₕ tuning of its transistor. In other words, a substantial part of the dopant profile will have migrated from the further metal layer 150 to the first metal layer 140.

In case the silicidation step shown in FIG. 1f does not cause the dopant profiles 152 and 154 to diffuse close enough to the interface between the thin metal layer 140 and the dielectric layer 130, the semiconductor device may be exposed to another thermal budget to complete the diffusion of these profiles to their preferred locations in the stack.

At this point, it is emphasized that the method of the present invention has substantial advantages over methods in which a dopant is directly implanted in a metal layer directly covering a gate dielectric layer. Because the location of dopant profiles 152 and 154 introduced into the thin metal layer 140 by means of diffusion can be controlled more accurately than the location of dopant profiles introduced by means of implantation, damage to the dielectric layer 130 by the unwanted migration of dopant species beyond the interface between the thin metal layer 140 and the dielectric layer 130 can be more effectively avoided.

FIG. 2 shows an alternative embodiment of the present invention. Compared to FIG. 1, the silicidation step of the further metal layer 150, shown in FIG. 2e, is performed prior to the gate patterning step, shown in FIG. 2f. The steps shown in FIG. 2 a-d are identical to the steps shown in FIG. 1a-d.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. The word “comprising” does not exclude the presence of elements or steps other than those listed in a claim. The word “a” or “an” preceding an element does not exclude the presence of a plurality of such elements. The mere fact that certain measures are recited in mutually different dependent claims does not indicate that a combination of these measures cannot be used to advantage.

1. A method of manufacturing a semiconductor device, comprising:
providing a substrate including a number of active regions and a dielectric layer covering the active regions; and
forming a stack of layers over the dielectric layer, comprising:
depositing a first metal layer having a first thickness over the dielectric layer;
depositing a second metal layer having a second thickness over the first metal layer, the second thickness being larger than the first thickness;
introducing a dopant into the second metal layer;
exposing the device to an increased temperature to migrate at least some of the dopant from the second metal layer beyond the interface between the first metal layer and the second metal layer; and
patterning the stack into a number of gate electrodes.

2. A method as claimed in claim 1, wherein the first metal layer has a higher solubility for the dopant than the second metal layer.

3. A method as claimed in claim 1, wherein the step of introducing the dopant into the second metal layer is executed prior to depositing the second metal layer over the first metal layer.

4. A method as claimed in claim 1, further comprising depositing a poly-silicon layer over the second metal layer, and wherein the step of increasing the temperature further comprises siliciding the second metal layer.

5. A method as claimed in claim 1, further comprising exposing the device to a further increased temperature to migrate at least some of the dopant beyond the interface.

6. A method as claimed in claim 1, wherein the first thickness is less than about 10 nm.

7. A method as claimed in claim 1, wherein the number of active regions comprises an active region of a first conductivity type and an active region of a second conductivity type, and wherein introducing a dopant into the second metal layer comprises:
selectively introducing a first dopant into a region of the second metal located over the active region of the first conductivity type; and
selectively introducing a second dopant into a region of the second metal located over the active region of the second conductivity type.

8. A method as claimed in claim 7, wherein the first dopant is selected from a group consisting of As and Te, and the second dopant selected from a group consisting of Al, In and F.

9. A semiconductor device comprising:
a substrate including a number of active regions;
a dielectric layer covering the active regions; and
a number of gate electrodes each located over one of said active regions, each gate electrode comprising a stack of layers comprising:
a first metal layer having a first thickness, deposited on the dielectric layer;
a second metal layer having a second thickness, deposited on the first metal layer, the second thickness being larger than the first thickness; and
a dopant profile located near the interface region between the second metal layer and the first metal layer, said dopant profile being shared by the first metal layer and the second metal layer.

10. A semiconductor device as claimed in claim 9, wherein each gate electrode further comprises a poly-silicon layer over the second metal layer, said second metal layer comprising a metal silicide.

11. A semiconductor device as claimed in claim 9, wherein the first metal layer has a higher solubility for the dopant than the second metal layer.

12. A semiconductor device as claimed in claim 9, wherein the first thickness is less than 10 nm.

13. A semiconductor device as claimed in claim 9, wherein the number of active regions comprises an active region of a first conductivity type and an active region of a second conductivity type, and wherein the number of gate electrodes comprises:
a first gate electrode located over the active region of the first conductivity type, said first gate electrode comprising a dopant profile of a first dopant type; and
a second gate electrode located over the active region of the second conductivity type, said second gate electrode comprising a dopant profile of a second dopant type.

14. A semiconductor device as claimed in claim 13, wherein the first dopant type is selected from a group consisting of As and Te, and the second dopant type is selected from a group consisting of Al, In and F.
